(19) United States
(12) Patent Application Publication
(10) Pub. No.: US 2003/0056899 A1
(43) Pub. Date: Mar. 27, 2003

(54) Semiconductor processing apparatus and manufacturing method of semiconductor device

(75) Inventor: Minoru Hanazaki, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/225,152

(22) Filed: Aug. 22, 2002

(30) Foreign Application Priority Data
Sep. 27, 2001 (JP) 2001-297351

(51) Int. Cl. H01L 21/306

(52) U.S. Cl. 156/345.25; 156/345.24

(57) ABSTRACT

A semiconductor processing apparatus can be gained that allows an increase in the yield of semiconductor devices with respect to a process carried out on the semiconductor substrate on which a semiconductor device is formed. A semiconductor processing apparatus is provided with the irradiation unit for irradiating the surface of the semiconductor substrate, on which a plurality of semiconductor chips are to be formed, with light at the time when a process is carried out on the semiconductor substrate, with the reflected light detection unit for detecting a plurality of reflected light beams, that are respectively reflected from the regions in which a plurality of semiconductor chips are to be formed and with the determination unit for detecting a plurality of termination points based on information gained by detecting the plurality of reflected light beams.

### BACKGROUND OF THE INVENTION

1. Field of the Invention

The present invention relates to a semiconductor processing apparatus and a manufacturing method of a semiconductor device, in particular, to a semiconductor processing apparatus wherein it is possible to detect the termination point of a process for each semiconductor chip that is formed on a semiconductor substrate in the process for the semiconductor substrate and a manufacturing method of a semiconductor device using this semiconductor processing apparatus.

2. Description of the Background Art

A semiconductor processing apparatus that utilizes plasma, such as a plasma etching apparatus, is in conventional use in a manufacturing step of a semiconductor device. In the following, an example of an etching apparatus is described. In such an etching apparatus, the termination point is required to be detected at the point in time when the etching process has been completed (point in time when the layer that is the object of etching has been completely removed through the etching process). As for a method for such termination point detection, a conventional method that utilizes the emission spectrum of the plasma used in the etching process is known. In this termination point detecting method that utilizes the emission spectrum of the plasma, a particular active species is selected from among active species (radical, ions, or the like) such as etching reactive products that are generated through the etching process and the termination point of the process is detected by measuring the emission intensity of the emission spectrum of this selected active species.

In the above described termination point detecting method that utilizes the emission spectrum of the plasma, however, there is a problem as follows. That is to say, the etching reactive products that are generated on the semiconductor substrate surface through etching spread throughout the entirety of the chamber wherein the etching process is carried out and, therefore, the so-called average value of the termination point for the entirety of the surface of the semiconductor substrate is detected in the conventional termination point detecting method that utilizes the emission spectrum of the plasma.

On the other hand, in the case that the uniformity of the plasma used in the etching process is poor, or in the case that the flow of the reactive gas or the exhaust of the etching reactive products becomes uneven, the uniformity of the etching process of the surface of the semiconductor substrate deteriorates. In such cases, when the etching process is completed by using the above described conventional termination point detecting method, a region wherein etching is locally insufficient (under-etched region) or a region wherein etching is excessively carried out (over etched region) are formed on the surface of the semiconductor substrate. As a result of this, a defect in the structure of semiconductor chips formed on the surface of a semiconductor substrate is caused so that a problem occurs wherein the semiconductor chip yield is lowered.

In addition, in many cases, conventionally, a plurality of one type of semiconductor chips is formed on the surface of one semiconductor substrate. In future, however, it is expected that a production method wherein a semiconductor substrate is processed under the condition wherein semiconductor chips including semiconductor devices of different types or of different sizes are mixed on the surface of one semiconductor substrate will be widely adopted. Thus, in the case that an etching process is carried out on a semiconductor substrate wherein a plurality of types of semiconductor chips are formed on the surface, the time for completing etching may vary (termination point may vary) depending on the type of semiconductor chip. On the other hand, in the conventional termination point detecting method that utilizes the emission spectrum of the plasma, the average value of the termination point of the entirety of the surface of the semiconductor substrate is detected as described above. Therefore, when the above described conventional termination point detecting method is used, there is a risk that the semiconductor chip yield will be further lowered because the defect occurrence ratio further increases such that etching becomes insufficient or etching is excessively carried out depending on the type of semiconductor chip.

### SUMMARY OF THE INVENTION

It is an object of the present invention to provide a semiconductor processing apparatus for implementing a termination point determining method wherein it is possible to increase the semiconductor device yield through a process for a semiconductor substrate on which the semiconductor device is formed and a manufacturing method of a semiconductor device using this semiconductor processing apparatus.

A semiconductor processing apparatus according to one aspect of this invention is a semiconductor processing apparatus for carrying out processing on a semiconductor substrate on which a plurality of semiconductor chips is to be formed, which is provided with: an irradiation unit for irradiating the surface of the semiconductor substrate on which a plurality of semiconductor chips is to be formed with light when processing on the semiconductor substrate is carried out; a reflected light detection unit for detecting a plurality of reflected rays that are respectively reflected from the regions in which the plurality of semiconductor chips are to be formed from among light with which the surface of the semiconductor substrate is irradiated; and a determination unit for detecting a plurality of termination points that are the points in time when processes are completed for respective processes carried out on the regions in which the plurality of semiconductor chips are to be formed based on the information gained by detecting the plurality of reflected rays.

Thus, the termination point, which is the point in time when the process is completed, can be individually detected with respect to each of the regions in which a plurality of semiconductor chips is to be formed on the surface of the semiconductor substrate. Therefore, the conditions of respective regions can be precisely grasped so that it becomes possible to set the timing of the process completion so as to allow the yield of the plurality of semiconductor chips formed on the semiconductor substrate to become of the maximum. Accordingly, it becomes possible to increase the yield of the plurality of semiconductor chips that are formed on the semiconductor substrate.

A manufacturing method of a semiconductor device according to another aspect of this invention uses the semiconductor processing apparatus according to the above described aspect.

In this case, the termination point of the process such as etching can be detected for each region in which a semiconductor chip is formed as a semiconductor device on the surface of the semiconductor substrate. Therefore, a defect of a semiconductor chip caused by insufficiency or excessiveness of the process can be prevented from occurring. Accordingly, the yield of the semiconductor device can be increased.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing a first embodiment of a semiconductor processing apparatus according to the present invention;

FIG. 2 is an expanded schematic view of a light projection part that forms an etching termination point determining unit in the semiconductor processing apparatus as shown in FIG. 1;

FIG. 3 is an expanded schematic view of a light reception part that forms an etching termination point determining unit in the semiconductor processing apparatus as shown in FIG. 1;

FIG. 4 is a schematic view showing a first example modification of the first embodiment of the semiconductor processing apparatus according to the present invention;

FIG. 5 is a schematic view showing a second example modification of the first embodiment of the semiconductor processing apparatus according to the present invention;

FIG. 6 is a schematic view showing a third example modification of the first embodiment of the semiconductor processing apparatus according to the present invention;

FIG. 7 is a schematic view for describing a fourth example modification of the first embodiment of the semiconductor processing apparatus according to the present invention;

FIG. 8 is a schematic view showing a second embodiment of a semiconductor processing apparatus according to the present invention;

FIG. 9 is an expanded cross sectional schematic view of a sample chamber of the semiconductor processing apparatus shown in FIG. 8;

FIG. 10 is a flow chart of a chip region distinguishing method in a termination point determining method according to the present invention;

FIG. 11 is a plain schematic view showing the surface of a wafer;

FIG. 12 is a schematic view for describing the chip region distinguishing method shown in FIG. 10;

FIG. 13 is a flow chart of a method for determining the irradiation wavelength used in a termination point determining method of a plasma process according to the present invention;

FIG. 14 is a graph of the emission spectrum of plasma in plasma processing;

FIG. 15 is a cross sectional schematic view showing the condition on a wafer in the case that the etching processing time is before the etching termination point in time (just in time etching);

FIG. 16 is a cross sectional schematic view of a wafer in the case that the etching processing time is approximately the same as the etching termination point in time (just in time etching);

FIG. 17 is a cross sectional schematic view of a wafer in the case that the etching processing time is later than the etching termination point in time;

FIG. 18 is a graph expressing the relationship between the etching time and the chip yield;

FIG. 19 is a flow chart for describing the termination point determining method for carrying out termination point determination of an etching process so that the chip yield becomes of the maximum in an etching apparatus according to the present invention;

FIG. 20 is a block diagram showing the configuration of an etching apparatus according to the present invention for implementing the termination point determining method shown in FIG. 19;

FIG. 21 is schematic view for describing the step (S340) of determining the termination point of an etching process for each chip region;

FIG. 22 is a graph for describing over etching time for each chip region;

FIG. 23 is a graph for describing a method of predicting the yields of the chip regions 30a to 30c, respectively, according to over etching time by using the yield-over etching time function;

FIG. 24 is a flow chart for describing a sixth embodiment of the termination point determining method that is carried out in an etching apparatus according to the present invention;

FIG. 25 is a block diagram showing the configuration of an etching apparatus for carrying out the termination point determining method shown in FIG. 24; and

FIG. 26 is a flow chart for describing the step of automatically recognizing the type and the position of a chip region.

### DESCRIPTION OF THE PREFERRED EMBODIMENTS

In the following, the embodiments of the present invention are described referring to the drawings. Here, the same reference numbers are attached to the same or corresponding parts in the following drawings, of which the descriptions are not repeated.

(First Embodiment)

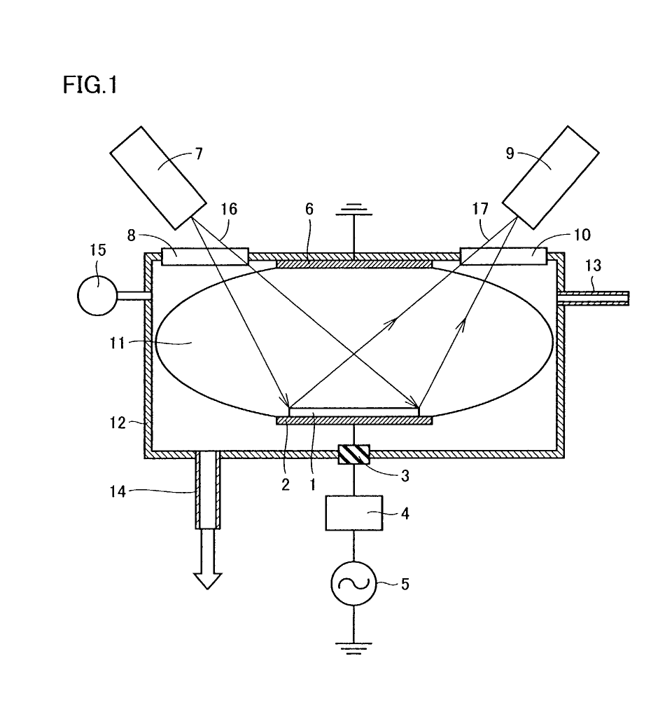

Referring to FIGS. 1 to 3, an etching apparatus is described as a semiconductor processing apparatus according to the present invention.

Referring to FIG. 1, the etching apparatus is an etching apparatus having a so-called parallel plate-type electrode structure. The etching apparatus is provided with a vacuum chamber 12, a lower electrode 2 that supports a wafer 1 as a semiconductor substrate inside of this vacuum chamber 12 and, at the same time, that becomes one of the electrodes and an upper electrode 6 that is installed on the upper wall surface of vacuum chamber 12 so as to face lower electrode 2. A high frequency power supply 5 is connected to lower electrode 2 via an impedance matching device 4. On the other hand, upper electrode 6 is grounded. Here, upper electrode 6 is at the same potential as vacuum chamber 12.

Wafer 1, which is the object that undergoes the etching process, is placed on lower electrode 2 into which a high frequency power is applied. The high frequency power that is applied to lower electrode 2 is supplied to lower electrode 2 via impedance matching device 4 from high frequency power supply 5. This supply system of high frequency power is isolated from vacuum chamber 12 by means of an insulator 3.

A gas introduction part 13 for introducing material gases (reactive gases) that are used to form plasma is connected to vacuum chamber 12. In addition, vacuum chamber 12 is provided with an exhaust vent 14 for venting unreacted gases or reactive products to the outside of vacuum chamber 12. In addition, vacuum chamber 12 is provided with a vacuum meter 15 for measuring the degree of vacuum of the inside of vacuum chamber 12.

A high frequency voltage is applied between lower electrode 2 and upper electrode 6 inside of vacuum chamber 12 and, thereby, plasma 11 is generated. Reactive gases supplied to the inside of vacuum chamber 12 from gas introduction part 13 are resolved and detached in plasma 11 so as to become active species or reactive ions. Then, a film, which is an object of etching, formed on wafer 1 is etched by using these active species, or the like. The reactive products that are generated from wafer 1 at the time of etching are vented to the outside of vacuum chamber 12 from exhaust vent 14 together with the unreacted gases.

Here, exhaust vent 14 is connected to a gas exhaust system (not shown) including a pump, and the like. A pressure control mechanism (not shown) for controlling the pressure inside of vacuum chamber 12 is provided within the gas exhaust system. By operating the above described pressure control mechanism based on the output data from vacuum meter 15, the gas pressure of the inside of vacuum chamber 12 is controlled to a predetermined value.

A window for an etching termination point determining unit is formed in the upper wall of vacuum chamber 12. Concretely, a window 8 for a light projection part is formed in one end portion of the upper wall of vacuum chamber 12 and a window 10 for a light reception part is formed in the other end portion that is located on the opposite side of the above end portion. A light projection part 7 is installed in a portion located above window 8 for the light projection part. The surface of wafer 1 is irradiated with irradiated light 16 emitted from light projection part 7. Reflected light 17 resulting from the reflection of irradiated light 16 on the surface of wafer 1 reaches a light reception part 9 via window 10 for the light reception part.

The termination point detecting method of etching using light projection part 7 and light reception part 9, shown in FIG. 1, is concretely described in the following. That is to say, when etching for the surface layer of wafer 1 progresses and, thereby, the etched layer (etched object) is removed, the component (hereinafter also referred to as base) located on the lower side of this etched object is exposed. Then, the material that forms the surface (surface of wafer 1) on which irradiated light 16, which is monochromatic light emitted from light projection part 7, is reflected changes from the etched object to the base. Therefore, the reflectance changes when irradiated light 16 is reflected on the surface of wafer 1. As a result of this, the intensity of reflected light 17 that enters light projection part 9 changes.

Then, reflected light 17 from wafer 1 is detected by using a plurality of photoelectric conversion elements (not shown) arranged inside light reception part 9. At this time, in the case that the positions of the respective chips on the surface of wafer 1 have been detected in advance, termination points of etching in these chips can be detected by monitoring the intensities of reflected light 17 from the positions where these chips exist. Thus, it becomes possible to carry out a termination point determination in the etching process for each of the plurality of chips formed on wafer 1.

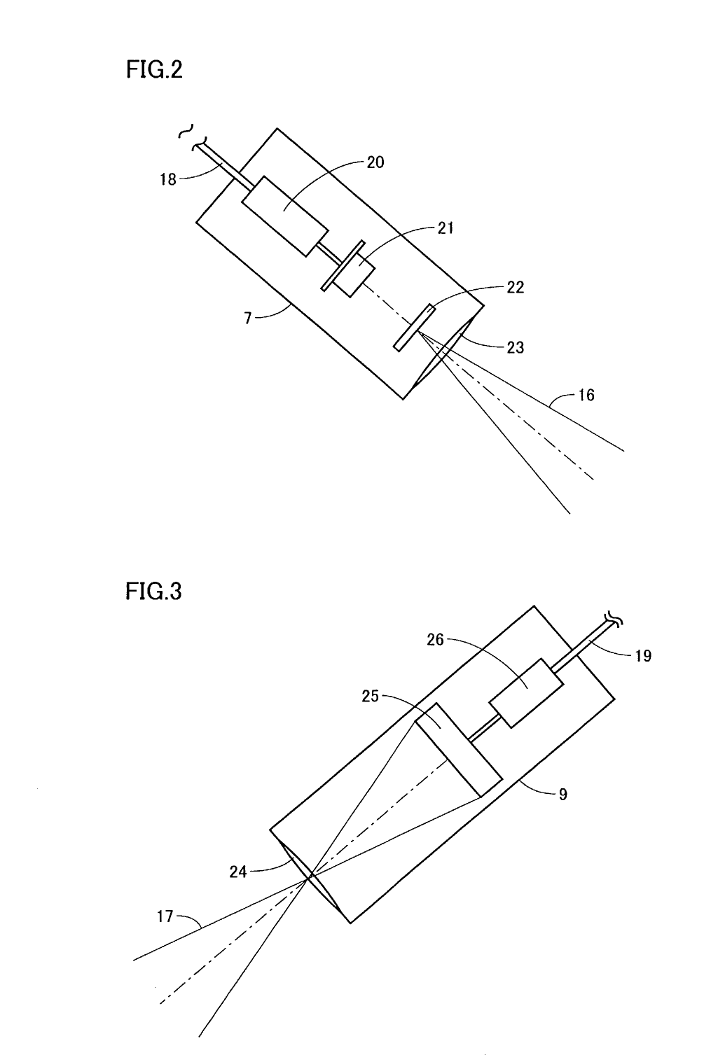

As for the configuration of light projection part 7 as an irradiation unit, the structure as shown in FIG. 2, for example, can be implemented. Referring to FIG. 2, light projection part 7 is provided with a light source 21 that generates light of a predetermined wavelength, a driving circuit 20 for driving light source 21, a beam expander 22 for spreading light by changing the emission direction of the light emitted from light source 21 to an arbitrary direction (allow the emission direction of the light to have a range of spread to a certain extent) and a light projection lens system 23. Driving circuit 20 is connected to a control part as a determination unit of the etching apparatus via a signal line 18.

As for the wavelength of the light generated by light source 21, it is preferable to select the wavelength wherein the ratio (S/N) of the reflectance (S) from the etched object to the reflectance (N) of the base located on the lower side of this etched object becomes great. For example, in the case that the etched object is an aluminum alloy film and the base is a silicon oxide film, a red semiconductor laser element, or the like, that can gain high power light at a comparatively inexpensive cost can be used for light source 21. Here, wafer 1 is irradiated with the light emitted from light source 21 after the emission direction of the light emitted from light source 21 is spread to an arbitrary solid angle by using beam expander 22 and light projection lens system 23.

In addition, the configuration of light reception part 9 as the reflected light detection unit can, for example, be implemented according to the configuration shown in FIG. 3. Light reception part 9 is provided with a light reception lens system 24, light reception element 25 and a signal amplification circuit 26. Signal amplification circuit 26 is connected to light reception element 25 and is also connected to the control part of the etching apparatus by means of a signal line 19. Light reception lens system 24 is arranged in front of light reception element 25.

Light reception element 25 is irradiated with reflected light 17 from wafer 1 that passes through light reception lens system 24 as shown in FIG. 3. A CCD array, or the like, that is formed of CCD (charge-coupled device) cells, which are a plurality of elements, can be used as light reception element 25. Thus, change in the intensity of the reflected light can be easily detected for each of the plurality of chips on the surface of wafer 1, as described above, by using light reception element 25 in a plane form.

In the etching apparatus having the above described configuration, reflected light 17 can be detected while the etching process is being carried out for each of the chips on wafer 1 as described above. Then, the etching termination point determination can be carried out for each chip according to a change in the intensity of this reflected light 17.

The conventional etching termination point determining method utilizes the emission spectrum of plasma during the etching process. In such a conventional etching termination point determining method, change in the light emission of plasma is detected in accordance with the reactive products from the entirety of wafer 1. Therefore, the termination point determination is carried out according to the average of the entirety of wafer 1 so that excessive etching (over etching) or insufficient etching (under etching) occur on a chip formed on wafer 1 in the case that a change in etching rate has locally occurred in wafer 1. Accordingly, the yield of chips formed on wafer 1 is lowered.

On the other hand, in the case that the etching termination point determination is carried out for each of the chips formed on wafer 1 as in the etching apparatus according to the present invention, the termination point of etching can be monitored in real time for each chip when a change in the etching rate has locally occurred in wafer 1. Then, as described below, it becomes possible to exercise control so that the etching process is completed according to the timing when the yield of chips becomes of the maximum (probability of gaining a good product becomes of the maximum). As a result of this, it becomes possible to increase the yield of chips formed on wafer 1 in comparison with the prior art.

In addition, in recent years the manufacture of different types of semiconductor chips mixed on one wafer 1 has been carried out. In such a case, when the types of chips differ from each other, the optimal etching termination point times respectively differ. In the conventional etching termination point determining method utilizing the emission spectrum of plasma, however, the etching is completed in an average time of etching completion time for several different types of chips. Therefore, in some cases, it is difficult to carry out an etching process that is suitable for all of the different types of chips.

On the other hand, in accordance with the etching apparatus according to the present invention, the control such that the etching process is completed according to the timing when the yield of the chips of which the priority is the highest (or of which the profit margin is the greatest) becomes comparatively high is made possible in the case that a plurality of types of chips are mixed and formed on wafer 1 by appropriately weighting each of the plurality of types of chips based on evaluation indications such as profit margin, profit amount per apparatus of quantity, or the like.

Here, the above described etching termination point determining unit according to the present invention is applicable in the etching apparatus having parallel plate electrodes in a capacitive coupling system as shown in FIG. 1 and it can also be applied in another semiconductor processing apparatus as long as the reflectance of light from the surface of the processed object changes together with the progress of the process in the semiconductor processing apparatus. As for an etching apparatus, for example, the etching determination point determining unit according to the present invention can be applied to an etching apparatus of an inductive coupling system (ICP system) or to an etching apparatus of an electron cyclotron resonance (ECR) system.

In addition, though the etching apparatus shown in FIG. 1 uses a high frequency (RF) power source as a power source for plasma generation, a power source of another frequency such as microwave may be used as a power source for generating plasma 11. In addition, though the etching apparatus shown in FIG. 1 is provided with gas introduction part 13 on the sidewall of vacuum chamber 12 with respect to the arrangement position of gas introduction part 13 that greatly influences the uniformity of plasma 11, gas introduction part 13 may be provided in a position other than on the sidewall. For example, gas introduction part 13 may be provided in upper electrode 6.

In addition, though a silicon substrate can be used as wafer 1, a substrate made of another material such as a GaAs substrate, an InP substrate, or the like, may be used. The etching termination point determining unit according to the present invention can also be applied to these substrates.

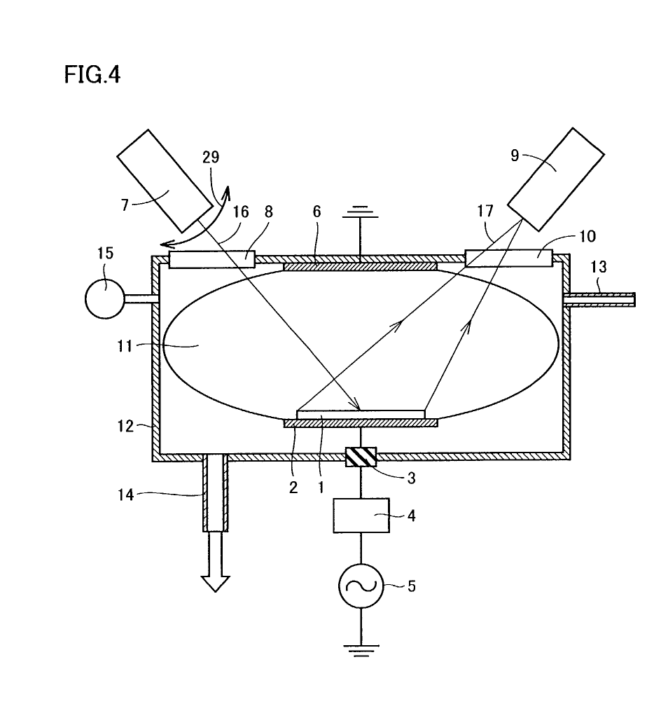

Referring to FIG. 4, a first example modification of a first embodiment of the etching apparatus according to the present invention is described. Here, FIG. 4 corresponds to FIG. 1.

Referring to FIG. 4, an etching apparatus is provided having a structure essentially similar to that of the etching apparatus shown in FIGS. 1 to 3 while the configuration of light projection part 7 differs. That is to say, in the etching apparatus shown in FIG. 4, light projection part 7 is not provided with a mechanism for spreading the solid angle of the irradiated light such as beam expander 22 as shown in FIG. 2. Therefore, beams in a line form, of which the emission directions are substantially all in a specific direction, are emitted from light projection part 7. In the etching apparatus shown in FIG. 4, however, light projection part 7 is shifted as shown by arrow 29 and, thereby, the irradiated light scans the surface of wafer 1. Here, though the scanning mechanism for shifting light projection part 7 is not specifically shown, a general scanning mechanism using a motor, cylinder, or the like, can be used.

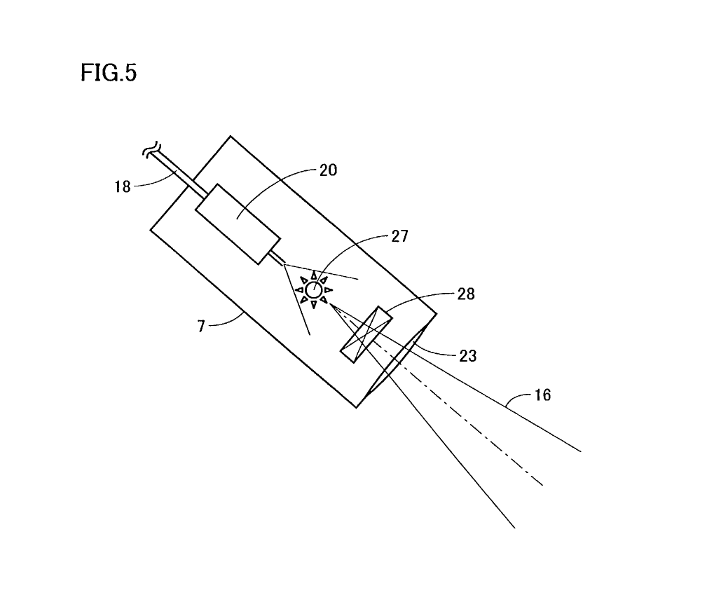

Referring to FIG. 5, a second example modification of the first embodiment of the etching apparatus according to the present invention is described. Here, FIG. 5 corresponds to FIG. 2 and shows a light projection part.

Referring to FIG. 5, in a light projection part 7 of an etching apparatus, a halogen lamp 27 is used not as a light source for emitting light of a particular wavelength but as a light source for releasing light of a variety of wavelengths. A filter 28 is installed so that light emitted from a white light source such as halogen lamp 27 passes through filter 28 (b)and pass filter) as a filter member. Filter 28 allows light of an arbitrary wavelength from among light from halogen lamp 28 to pass. By providing this filter 28, only emission of light of a predetermined wavelength from light projection part 7 is allowed. Then, by replacing this filter 28, the wavelength of light emitted from light projection part 7 can be arbitrarily changed.

In addition, another light source may be used in place of halogen lamp 27. As for the other light source, a light source, which emits light of a plurality of wavelengths, may be used. Thus, the combination of the light source and filter 28 is properly changed according to the required wavelength and, thereby, it becomes possible to emit light of a predetermined wavelength from light projection part 7. Thus, such effort as the replacement of light projection part 7 for every process according to the combination of the etched object and the base can be avoided. As a result of this, the efficiency (productivity) in etching processes can be increased.

Here, though FIG. 5 shows a configuration of extracting light of an arbitrary wavelength through the combination of a light source that releases light of a variety of wavelengths and filter 28, a laser (wavelength variable laser) that can change the wavelength, such as an excimer laser or an Ar ion laser, as a unit for changing the wavelength of light, may be used as light source 21. In such a case, the same effect as the effect due to light projection part 7 shown in FIG. 5 can be gained.

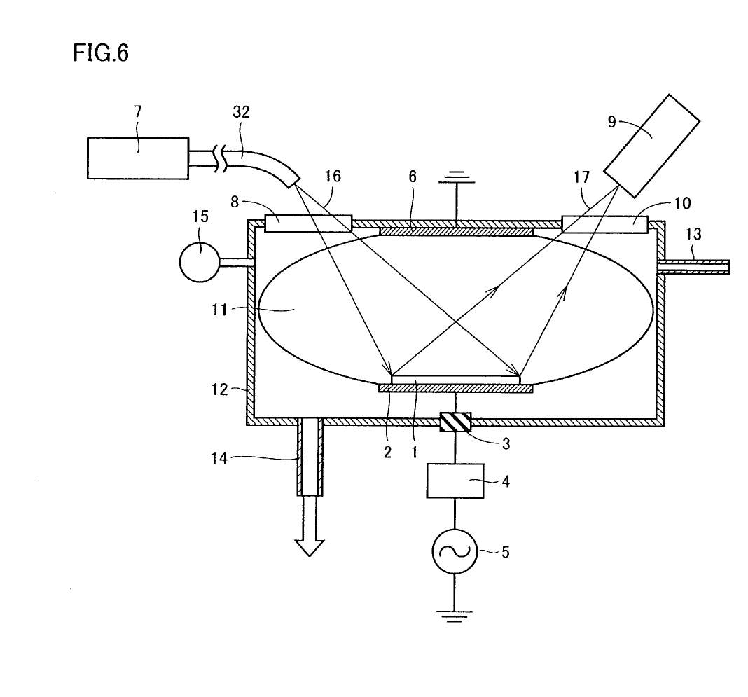

Referring to FIG. 6, a third example modification of the first embodiment of the etching apparatus according to the present invention is described. Here, FIG. 6 corresponds to FIG. 1.

Referring to FIG. 6, an etching apparatus is essentially provided with a similar structure as of the etching apparatus shown in FIGS. 1 to 3 and the configuration of the light projection part differs. That is to say, in the etching apparatus shown in FIG. 6, a light projection part 7 is installed in a position located a certain distance away from a vacuum chamber 12 and an optical fiber 32 is connected to light projection part 7. The irradiated light emitted from this light projection part 7 is guided to the inside of vacuum chamber 12 via optical fiber 32. In this case, the same effect as in the etching apparatus shown in FIGS. 1 to 3 can be gained and, at the same time, the degree of freedom of arrangement of light projection part 7 can be made great in the etching apparatus.

Here, though FIG. 6 shows the configuration wherein optical fiber 32 is connected to light projection part 7, light reception part 9 may be placed in a position away from vacuum chamber 12 and an optical fiber, or the like, may be connected to light reception part 9 in order to guide reflected light 17, which is reflected from wafer 1, to this light reception part 9 in the configuration. In this case, the degree of freedom of the arrangement of light reception part 9 can be made large.

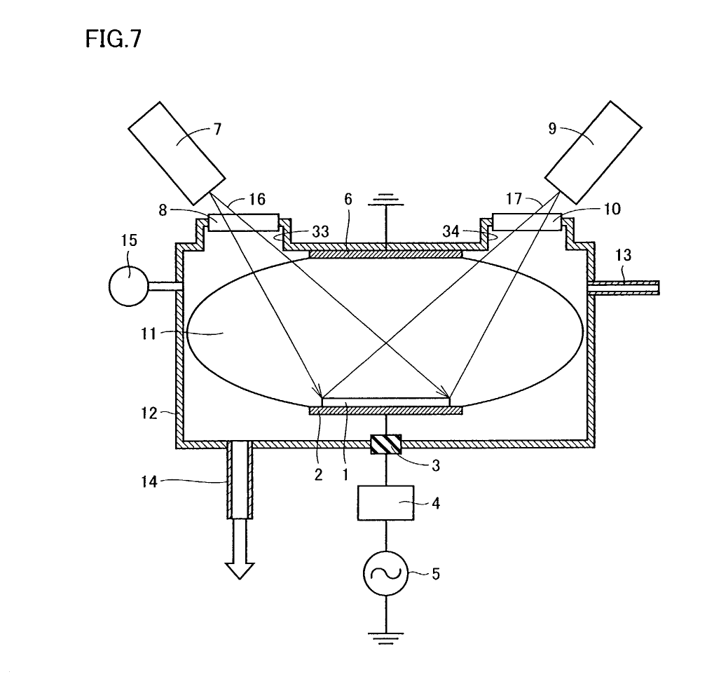

Referring to FIG. 7, a fourth example modification of the first embodiment of the etching apparatus according to the present invention is described. Here, FIG. 7 corresponds to FIG. 1.

Referring to FIG. 7, an etching apparatus is essentially provided with a similar structure to the etching apparatus shown in FIGS. 1 to 3 and the structure of the portions where window 8 for the light projection part and window 10 for the light reception part differs. That it to say, recesses 33 and 34 are created in the upper wall of a vacuum chamber 12 so that window 8 for the light projection part and window 10 for the light reception part are respectively provided at the bottoms of these recesses 33 and 34.

Here, when the etching process is continued window 8 for the light projection part and window 10 for the light reception part allow, reactive products due to the etching or plasma 11, or the like, to attach to the surfaces thereof. Therefore, smears are gradually generated on window 8 for the light projection part and on window 10 for the light reception part. When window 8 for the light projection part and window 10 for the light reception part become smeary the amount of light of irradiated light 16, with which wafer 1 is irradiated, and reflected light 17, which enters light reception part 9, is reduced. As a result of this, in some cases, the precision of the termination point determination deteriorates.

As shown in FIG. 7, however, recesses 33 and 34 may be created in the upper wall of vacuum chamber 12 and window 8 for the light projection part and window 10 for the light reception part may be provided at the bottom thereof and, thereby, the distance between window 8 for light projection part, window 10 for the light reception part and plasma 11 can be made sufficiently large. As a result of this, the problems wherein window 8 for the light projection part and window 10 for the light reception part become smeary due to plasma, or the like, as described above can be prevented from occurring.

In addition, as for the structure of the portions wherein window 8 for the light projection part and window 10 for the light reception part are provided, a simple recess structure may be provided as shown in FIG. 7, or a structure (so-called labyrinth structure) wherein plasma 11 is prohibited from reaching window 8 for the light projection part and window 10 for the light reception part may be provided as a more complicated structure. Here, a plasma cleaning process may be carried out on window 8 for the light projection part and on window 10 for the light reception part during the etching process.

Though the case wherein the termination point determining unit according to the present invention is applied to an etching apparatus is described in the above, the present invention can also be applied to an ashing apparatus, a thin film formation apparatus, an ion injection apparatus, a spattering apparatus, or the like, in addition to an etching apparatus. Furthermore, it can be applied not only to an apparatus for carrying out a so-called dry process but also to a wet processing apparatus that uses liquid chemicals.

(Second Embodiment)

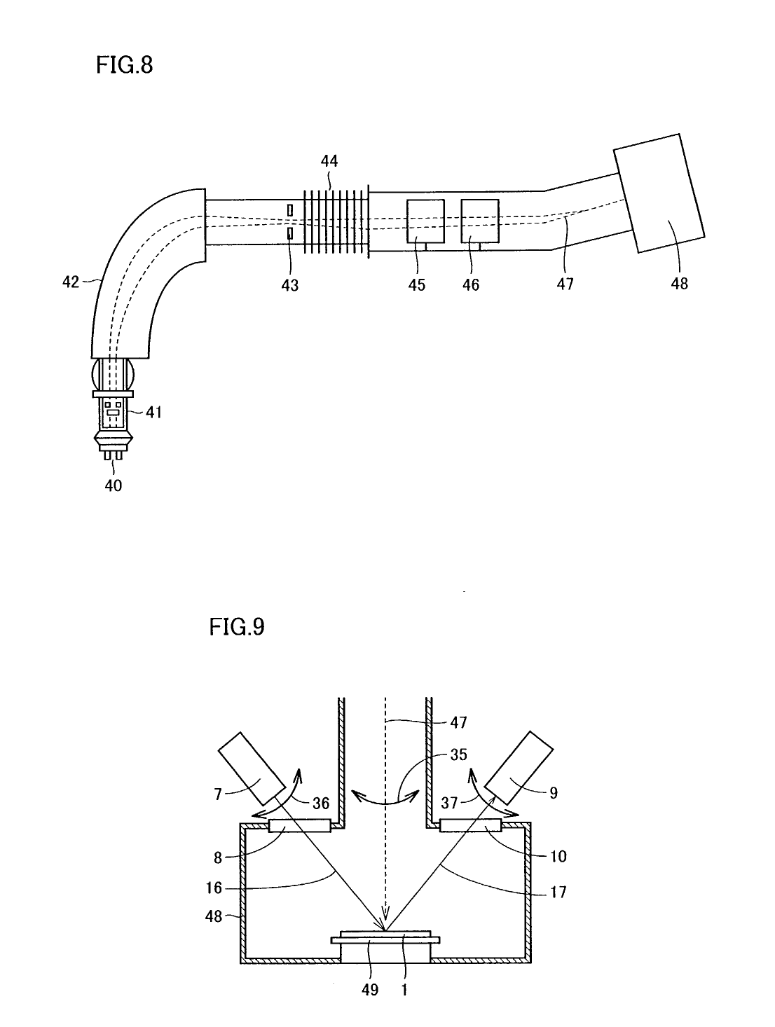

Referring to FIGS. 8 and 9, a second embodiment of a semiconductor processing apparatus according to the present invention is described. Here, a semiconductor processing apparatus shown in FIG. 8 is an ion injection apparatus.

Referring to FIGS. 8 and 9, an ion injection apparatus (an ion implanter) as a semiconductor processing apparatus is provided with a high voltage power supply 40, an ion extraction electrode 41, a mass analyzing magnet 42, a variable slit 43, an acceleration tube 44, a Y scanning electrode 45, an X scanning electrode 46 and a sample chamber 48. An ion beam released from ion extraction electrode 41 passes through variable slit 43 after passing through mass analyzing magnet 42. The ion beam that has passed through this variable slit 43 is accelerated to a predetermined energy level in acceleration tube 44. After that, ion beam 47 is scanned so as to spread in the direction perpendicular to the direction in which the ion beam progresses by Y scanning electrode 45 and X scanning electrode 46.

A sample support 49 (see FIG. 9) is installed in a region that is irradiated with ion beam 47 in sample chamber 48. As shown in FIG. 9, a wafer 1 is placed on sample support 49. As shown by arrow 35, ion beam 47 is scanned by Y scanning electrode 45 (see FIG. 8) and X scanning electrode 46 (see FIG. 8). Therefore, the entirety of the surface of wafer 1 is irradiated with ion beam 47.

A window 8 for a light projection part and a window 10 for a light reception part are arranged in sample chamber 48 in the same manner as in the etching apparatus shown in FIG. 1. A light projection part 7 is placed above window 8 for the light projection part. In addition, a light reception part 9 is placed above window 10 for the light reception part. Light projection part 7 is movable as shown by arrow 36 so that the entirety of the surface of wafer 1 can be irradiated with the irradiated light. In the same manner, light reception part 9 is also movable as shown by arrow 37 so that reflected light that reflects from the entirety of the surface of wafer 1 can be received.

The termination point determining unit according to the present invention shown in the first embodiment of the present invention can also be applied to the ion injection apparatus as shown in the above. That is to say, when wafer 1 is irradiated with ion beam 47, ions are injected into wafer 1. Then, the physical properties of the surface of wafer 1 change according to the depth of the above doped ions from the surface of wafer 1 and according to the doping amount of the ions. The reflectance of light on the surface of wafer 1 changes according to this change of physical properties of the surface. Therefore, by monitoring the fluctuation of the reflectance of light from the surface of wafer 1, it becomes possible to carry out, in real time, determination of the charge amount of the ion injection (ion injection amount) or examination of the injection characteristics.

On the other hand, in the case that another group of ions that has, for example, the same amount of charge is injected into wafer 1, it is difficult to detect or prevent such a mistaken injection wherein different ions are injected according to a determination method of the injection charge amount by means of a conventional measurement of current due to an ion beam. However, in the case that ions other than predetermined ions are injected, the material characteristics of the surface of wafer 1 exhibits a change that differs from a predetermined change and, thereby, the reflectance of light from the surface thereof changes to a value that differs from a predetermined value in some cases. Therefore, when the reflectance of light from the surface of wafer 1, wherein ion injection is carried out, is measured in real time as in the present invention, a mistaken injection of ions can be easily detected due to a change of the reflectance in the case that ions are mistakenly injected.

Here, in the apparatus shown in FIG. 9, under the condition where wafer 1 is irradiated with ion beam 47 as described above, the region, which is irradiated with ion beam 47, is irradiated with irradiated light 16 from light projection part 7 so that reflected light 17 resulting from the reflection of the irradiated light from the surface of wafer 1 is detected by light reception part 9 and, thereby, the termination point determination of the ion injection amount is carried out. However, in the case that the present invention is applied to the usage other than the terminal point determination of the ion injection amount, the reflectance of light from the surface of wafer 1 may be measured in a different apparatus or in a different position after ion injection into wafer 1 has been carried out.

(Third Embodiment)

In the above described first and second embodiments of the present invention, an apparatus configuration is shown wherein reflected light from wafer 1 is received by light reception elements such as CCDs, inside of light reception part 9, so that the termination point determination of the etching of the respective chips on wafer 1, or the like, is carried out based on the data gained in the above manner. In this case, it is necessary to distinguish the reflected light components from the respective chips formed on wafer 1 in the reflected light. In the following, a method of receiving reflected light from wafer 1 by means of light reception elements and of recognizing the reflected light components (signals) from the respective chips formed on wafer 1 from the output data gained in the above manner is described.

In general, in the case that a plurality of chips are formed on wafer 1, a dicing step for separating wafer 1 into respective chips is carried out after the steps (so-called first half process) such as a film formation on wafer 1 or an etching process are carried out. Therefore, dicing lines are usually provided in advance, at the exposure stage, on wafer 1 so as to indicate positions that are to be cut by a dicing saw. Accordingly, the portions surrounded by these dicing lines are, in advance, recognized as regions (chip regions) in which individual chips are formed and, thereby, reflected light from these chip regions can be distinguished afterwards. Then, the termination point determining process is carried out based on the reflected light from each of these chip regions so that the termination point determination can be carried out for each of the chip regions. In the following, the step of recognizing a portion surrounded by dicing lines as a chip region is described.

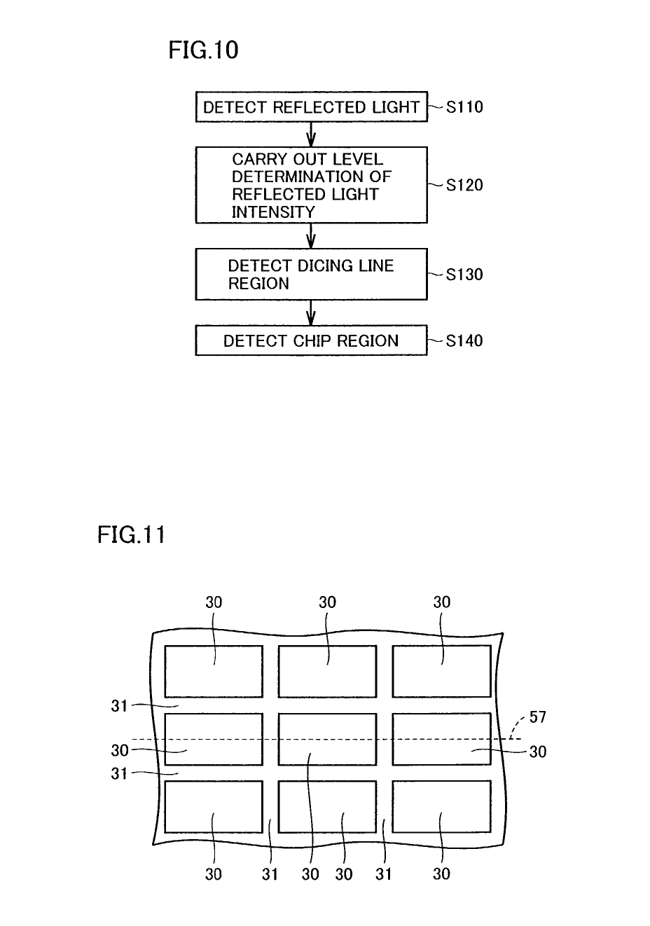

Referring to FIG. 10, according to a chip region distinguishing method, the surface of a wafer that is the measured object is first irradiated with radiation light from a light projection part and, at the same time, the step (S110) of detecting received light, which is reflected from the surface of wafer, in a light reception part is implemented. At this time, as shown in FIG. 11, the surface of wafer is in a condition wherein chip regions 30 surrounded by dicing lines 31 (also referred to as dicing line regions) are arranged in a matrix. Here, the intensity of the reflected light is measured, for example, along a line 57 and, then, the intensity of the reflected light that is reflected from chip regions 30 is comparatively high while the intensity of the reflected light that is reflected from dicing lines 31 is comparatively low. This is because the surface conditions of dicing lines 31 (regions other than the regions wherein chip regions 30 are to be formed as semiconductor chips) and of chip regions 30 (regions wherein semiconductor chips are to be formed) differ and, therefore, respective light reflectance differs.

Next, the step (S120) of carrying out a level determination of the detected intensity of the reflected light is implemented. That is to say, since there is a difference, as described above, between the intensities of the reflected light respectively from chip regions 30 and dicing lines 31, an appropriate determination level can be set with respect to the intensities of reflected light so that the portions of the reflected light of which the intensity is lower than the determination level can be determined as from dicing lines 31. As a result of this, the step (S130) of detecting the dicing line regions (dicing lines 31) can be implemented.

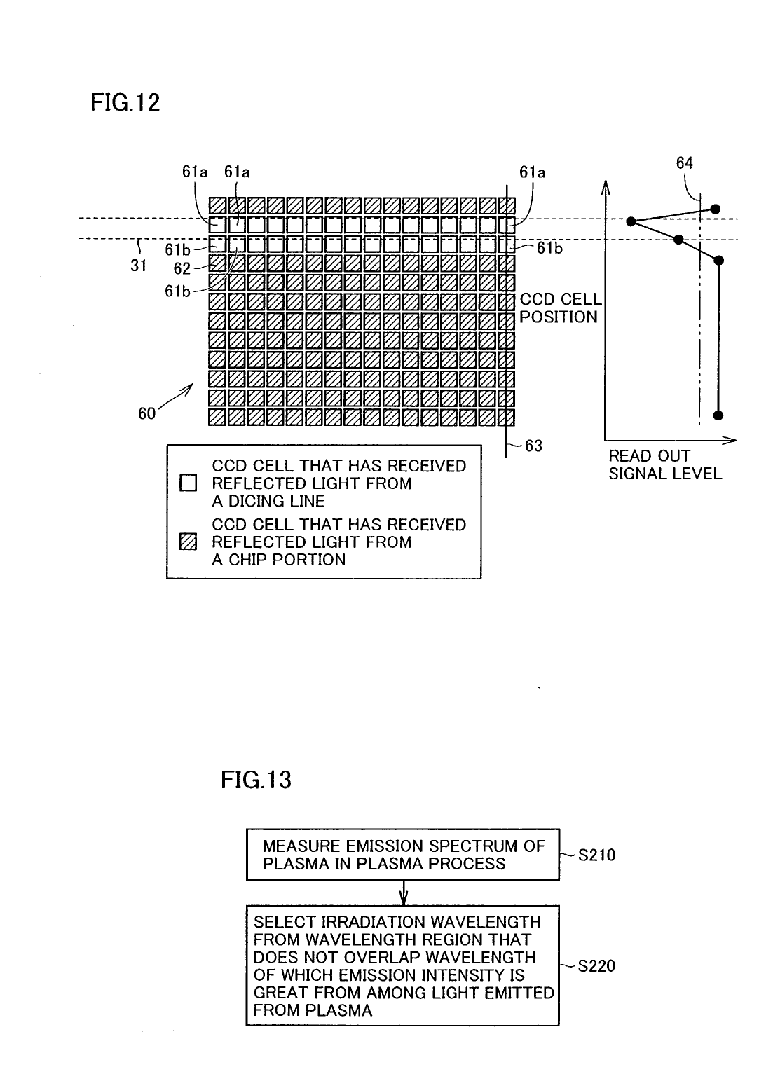

Then, since these portions surrounded by dicing lines 31 are chip regions 30, the step (S140) of detecting these portions surrounded by dicing lines 31 as chip regions can be implemented. In the following, further details are given referring to FIG. 12.

FIG. 12 shows a portion of a CCD array 60 that is a light reception element installed in light reception part 9. Referring to FIG. 12, a plurality of CCD cells that are photoelectric conversion elements are arranged in a matrix in CCD array 60. Then, in the case that reflected light from wafer 1 enters CCD array 60 in the step (S110) of detecting reflected light, as shown in FIG. 12, CCD cells 61a and 61b, wherein reflected light from dicing lines 31 enters, receives reflected light of a comparatively low intensity. On the other hand, CCD cells 62, wherein reflected light from chip regions enter, receives reflected light of a comparatively high intensity.

Then, in the step (S120) of carrying out a level determination of the intensity of the reflected light, when a command signal for reading out an output signal for each of the CCD cells of CCD array 60 is sent from a control apparatus, the output signal of each of the CCD cells is sequentially transmitted to the control part.

The dicing line regions and the chip regions are detected based on these output signals from the CCD cells. For example, a signal from the CCD cells along a reflected light measurement line 63 in the figure is shown in a region on the right side of FIG. 12. As is seen in FIG. 12, since the intensity of the reflected light from the chip portions (chip regions) is comparatively high, the output signals from the CCD cells that have received reflected light from these chip regions are comparatively high in level. On the other hand, the level of the output signals (read out signals) from CCD cells 61a and 61b, that have received reflected light from dicing lines 31 is comparatively low. In addition, it is understood that in CCD cells 61a and 61b wherein reflected light from dicing lines 31 has entered, the level of the read out signals from CCD cells 61a, of which the area of the regions that have received reflected light from dicing lines 31 is comparatively large, is lower than the level of the read out signals from CCD cells 61b, of which the area of regions that have received reflected light from dicing lines 31 is comparatively small.

Then, a determination level 64 is set for these read out signals. Regions on wafer 1 that correspond to the CCD cells of which the read out signal level is lower than this determination level 64 (regions on wafer 1 wherein reflected light enters CCD cells 61a and 61b) are determined to be dicing lines 31 in the step (S130) of detecting the dicing line regions. Then, in the step (S140) of detecting the chip regions, the regions surrounded by dicing lines 31 can be determined to be chip regions.

Here, in the case that a plurality of wafers of which the arrangement of chip regions on wafer 1 are the same are processed, such a determination of the chip regions may be carried out one time for each type of such wafers before implementing the respective etching processes. Then, after that, the pattern of the chip regions may be memorized in the processing apparatus so that it is not particularly necessary to carry out the chip position determination from the next etching process.

The chip regions on wafer 1 can be recognized in such a manner. As a result of this, a change in intensity of the reflected light from the respective chip regions on wafer 1 can be distinguished and, thereby, the termination point determination can be carried out for each of the chip regions based on this change in intensity of the reflected light.

Here, though CCDs are used as the above described light reception elements, the determination of the chip positions can be carried out in the same manner by using other photoelectric conversion elements (for example, CMOS elements). In addition, though a CCD element made up of a plurality of sensors (CCD cells) is used as a light reception element, another element, for example a photomultiplier tube or other vacuum image pickup tubes, may be used.

In order to carry out a determination of the dicing lines by using the above described photomultiplier tube, or the like, first, the distribution of the reflected light from wafer 1 is measured by allowing light reception part 9 to mechanically or electrically scan wafer 1 so that the reflected light from the entirety of the surface of the wafer can be detected in light reception part 9. Of course, light reception part 9, which contains a CCD of a single cell, may be mechanically or electrically shifted relative to wafer 1 so as to carry out scanning and to measure the distribution of the reflected light.

In addition, though the above example is described by using a case wherein the reflectance of light from dicing lines 31 is lower than the reflectance of light from the chip regions, there may be a case wherein the intensity of the reflected light from dicing lines 31 is greater than the intensity of the reflected light from the chip regions depending on the wavelength of light with which wafer 1 is irradiated. In this case, when regions exhibiting an intensity exceeding the determination level of the reflected light intensity are determined to be the dicing line regions, dicing lines 31 and chip regions 30 that are surrounded by these dicing lines 31 can be distinguished in the same manner as in the above described case. As a result of this, the same effects as in the above described method can be gained.

In addition, in light reception part 9 a filter may be installed on the front surface of light reception element 25 so that optical noise from the plasma or from the environment is reduced by using this filter. In this case, the sensitivity (S/N ratio) of light reception element 25 can be increased. As a result of this, dicing lines 31 and chip regions 30 can be detected with a higher degree of precision. Here, the method of distinguishing chip region 30 described in this third embodiment may be carried out before the below described step of carrying out the actual termination point determination in the termination point determining method (see the fifth and sixth embodiments of the present specification) according to the present invention.

(Fourth Embodiment)

As has already been described, in the termination point determining method of a plasma process, such as an etching process, according to the present invention, the surface of a wafer, which is the processed material, is irradiated with light from the outside and the reflected light resulting from the light reflected from the wafer surface is detected and, thereby, a change on the wafer surface is detected so as to carry out the termination point determination of the plasma process. Thereby, in the case that the wavelength of light with which the wafer surface is irradiated and the wavelength of light emitted from plasma that is used in the plasma process overlap each other, the detection precision of the reflected light from the wafer surface if lowered. In this case, it becomes difficult to carry out the termination point determination with a high precision. Accordingly, in the termination point determining method according to the present invention it is preferable to use light of a wavelength region differing from the wavelength of emitted light of plasma as light with which the wafer is irradiated. In the following, a method of determining the wavelength of light with which the wafer is irradiated (irradiation wavelength) is described.

Referring to FIG. 13, a method of determining the wavelength of light with which the surface of a wafer is irradiated is described in the present invention.

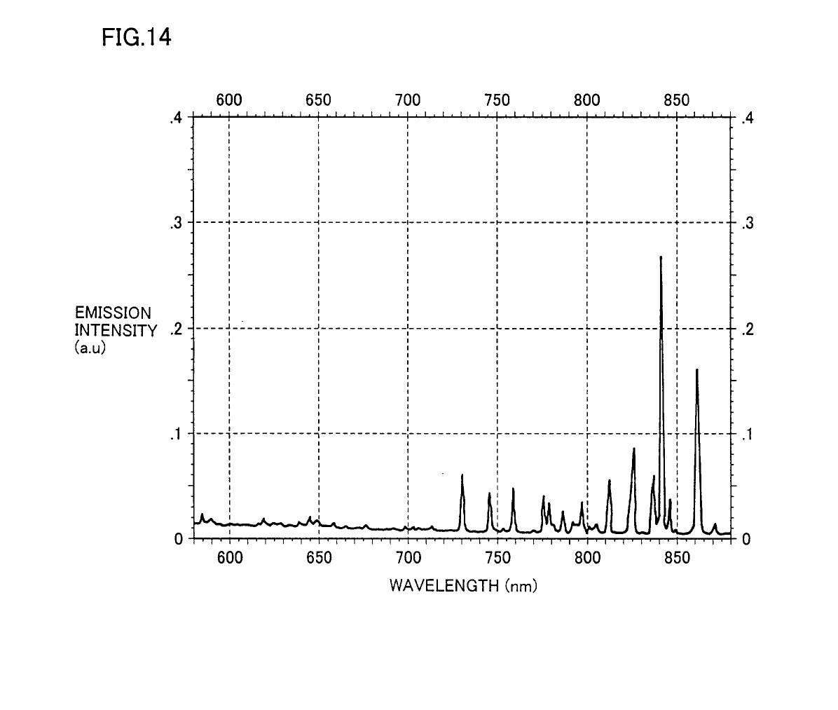

Referring to FIG. 13, first, the step (S210) of measuring the emission spectrum of plasma in a predetermined plasma process such as an etching process is implemented. As a result of this, as shown in FIG. 14, the emission spectrum data of the plasma can be gained. FIG. 14 shows an emission spectrum of the plasma at the time when an aluminum alloy film is etched in a plasma. The measurement conditions of data shown in FIG. 14 are as follows. Here, the plasma is generated through electric discharge in a magnetron. The reactive gas used for the etching is a mixture gas of chlorine gas and boron tri-chloride gas. As for the used values for the amounts of flow, the flow of chlorine gas is 0.08 liters/min (80 sccm) and the flow of the boron tri-chloride gas is 0.02 liters/min (20 sccm). In addition, the high frequency power supplied to the electrode is 400 W and the degree of vacuum within the vacuum chamber is 15 mTorr at the time of measurement. In addition, the intensity of the applied magnetic field is 150 G.

Referring to FIG. 14, the lateral axis indicates the wavelength (apparatus: nm) of light emitted from plasma while the longitudinal axis indicates the emission intensity (apparatus: arbitrary apparatus (a.u.)). As is seen in FIG. 14, a plurality of peaks of the emission spectrum of primarily chlorine radicals can be observed in the wavelength region from 730 nm to 860 nm in the emission spectrum of the plasma in the etching process under the above described conditions.

In the wavelength region from 580 nm to 730 nm, however, no remarkable peaks in the emission intensity are seen. Accordingly, it is preferable to use light of any of the wavelengths in this wavelength region (580 nm to 730 nm), wherein no remarkable peaks in the emission intensity are seen, as the wavelength of light with which the surface of wafer is irradiated. That is to say, as shown in FIG. 13, after the step (S210) of measuring the emission spectrum of the plasma, as shown in FIG. 14, is implemented, the step (S220) of selecting irradiation wavelengths from among the wavelength region wherein the light emitted from the plasma does not overlap the wavelength of which the emission intensity is great is implemented.

Here, the wavelength region of from 580 nm to 730 nm corresponds to the wavelength region wherein the above described light emitted from the plasma does not overlap the wavelength of the light component having a comparatively great emission intensity. And, the aluminum alloy film that is the etched object has an average light reflectance in the visible light range of 90%, or greater. Therefore, when the light reflectance for the etched object is taken into consideration, a red semiconductor laser beam of which the wavelength is 670 nm can be used as light with which the surface of the wafer is irradiated. Here, the wavelength of light with which the surface of the wafer is irradiated can be appropriately selected according to the conditions of the plasma process or to the etched object.

Thus, the termination point determination of the etching of the aluminum alloy film can be stably carried out without being influenced by light emitted from the plasma in the plasma process for etching the aluminum alloy film.

In addition, as for the light source of the irradiation light, another light source can be used as long as it is a light source that can release light of the wavelength that is positioned in the above described wavelength region (580 nm to 730 nm). For example, an He—Ne laser of which the wavelength is 632.8 nm can also be used as a light source.

In addition, light of another wavelength can be used as the irradiation light as long as it is light that does not interfere with the light component emitted from the plasma. For example, light in a wavelength region other than the wavelength region (580 nm to 880 nm) as shown in FIG. 14 and light of the wavelength that does not interfere with the light component emitted from the plasma can be used as the irradiation light. In addition, as for the selection range of the wavelength of the irradiation light, it is not necessary to limit it to the wavelength region (580 nm to 880 nm) as shown in FIG. 14 but, rather, the wavelength of the irradiation light may be selected from other wavelength regions. Thus, the wavelength or the width of the wavelength of the light source of the irradiated light used for the termination point determination are made to not overlap the wavelength of the light component emitted from the plasma at the time of the plasma process and, thereby, it becomes possible to carry out the termination point determination with a high precision by utilizing the reflected light from the wafer. Here, it is preferable for the method of deciding the irradiation light wavelength, which is described in this fourth embodiment, to be implemented before the step of carrying out the actual termination point determination in the below described termination point determining method (see the fifth and sixth embodiments of the present specification) according to the present invention.

(Fifth Embodiment)

In the following, a method for completing a plasma process according to a timing wherein the yield of the chips formed on the wafer becomes of the maximum is described with respect to the termination point determining method of a plasma process according to the present invention. Here, in the following, a case where an etching process is carried out on a wafer in the step (manufacturing step of a semiconductor device) of forming a semiconductor device, such as memory elements, on a wafer is described as an example of the plasma process.

The present inventor has discovered that in the case that an etching process is carried out, there is a specific type of correlation between the period of time of the etching process and the probability of gaining a good product with respect to the chips formed on the wafer. This is described in the following.

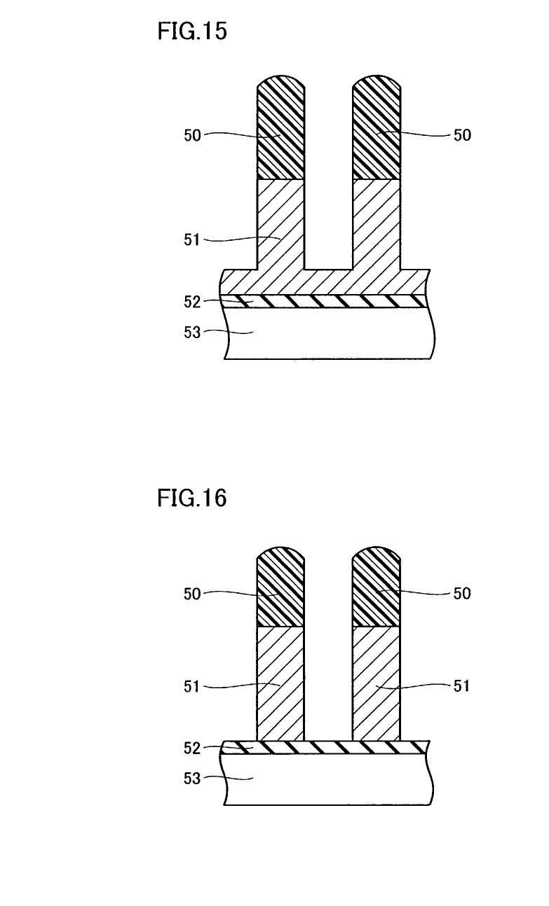

Referring to FIGS. 15 to 17, a silicon oxide film 52 is formed on the surface of a silicon substrate 53 that is a wafer. An aluminum alloy film 51, which is the etched object, is formed on silicon oxide film 52. A resist 50, which is used as a mask for etching and which has a predetermined pattern, is placed on aluminum alloy film 51.

As shown in FIG. 15, in the case that the period of time of the etching process is short in comparison with the period of time needed for etching termination, aluminum alloy film 51 that is the etched object remains so as to extend to the region other than the region located below resist 50. Therefore, aluminum alloy film 51 is in a condition wherein the regions located beneath resist 50 are connected to each other through the above described remaining portion of aluminum alloy film 51. Here, in the case that, for example, portions of aluminum alloy film 51 located beneath resist 50 is formed as electrodes, these electrodes are in a short circuited condition. As a result of this, as shown in FIG. 15, it becomes difficult for a chip that is a semiconductor element wherein electrodes made of aluminum alloy film 51 are short circuited to continue to maintain a normal operation. That is to say, the probability of gaining a good product becomes low.

Next, as shown in FIG. 16, in the case that the period of time of the etching process is approximately equal to the period of time needed for the etching termination, aluminum alloy film 51 is almost completely removed through etching in the regions other than the region located beneath resist 50. Therefore, no other portions of the aluminum alloy film 51 remain between portions of aluminum alloy film 51 located beneath resist 50 and, therefore, the portions of aluminum alloy film 51 located beneath this resist 50 are in the condition wherein they are isolated from each other. In this case, the structure of the chips wherein such an aluminum alloy film 51 is used for electrodes, or the like, is approximately equal to the designed structure and, therefore, the possibility of such chips operating normally is high. That is to say, the possibility of gaining a good product can be made high.

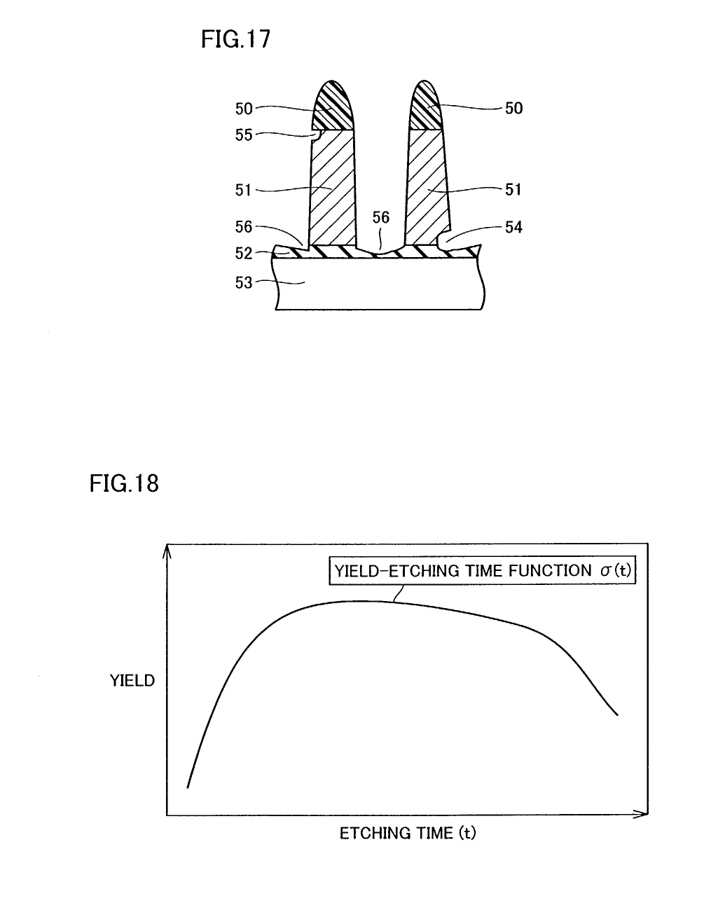

In addition, as shown in FIG. 17, in the case that the period of time of the etching process is longer than the period of time needed for the etching termination, the etching process is further continued to exceed the period of time needed for etching termination. Then, as shown in FIG. 17, the sidewalls of aluminum alloy film 51 are exposed to the plasma for a long period of time. Therefore, the sidewalls of aluminum alloy film 51 are etched in the lateral direction so as to create a so-called missing corner structure (side etched structure 55). In addition, due to the same reasons, a side etched structure 54 is created in the lower portion of aluminum alloy film 51. In addition, since the plasma contacts the silicon oxide film, which is a base film of aluminum alloy film 51 that is the etched object, for a long period of time, a region wherein the surface of silicon oxide film 52 is shaved off (oxide film shaved portion 56) is formed through this plasma. Then, in some cases, as a final form, an aperture that passes through silicon oxide film 52 is created depending on the length of the period of time of etching.

The creation of an aperture that passes through silicon oxide film 52, which is an insulating film, deteriorates the reliability of the isolation due to this silicon oxide film. In addition, side etched structures 54 and 55 reduces the dimensions of aluminum alloy film 51 so as to be smaller than the designed value in the lateral direction. As a result of this, signal transmission characteristics, or the like, deteriorate in the case that this aluminum alloy film 51 is used as a conductive line for transmitting an electrical signal, or the like. Then, aluminum alloy film 51 is locally cut off depending on the dimensions of the side etched structures 54 and 55. In such a case, the chip can no longer operate normally. That is to say, the probability of gaining a good product is lowered.

As described above, there is a specific type of correlation between the period of time of the etching process and the probability of gaining a good product (yield). Referring to FIG. 18, the lateral axis represents the period of time of etching (t) while the longitudinal axis represents the yield (probability of gaining a good product). Then, in the region where the period of time of the etching process is shorter than the period of time needed for etching termination, as has been already described, the yield becomes comparatively low. Then, in the region where the period of time of etching (period of time of the etching process) is approximately equal to the period of time needed for the etching termination, the yield becomes comparatively high and, furthermore, the period of time of the etching process becomes long, side etched structures 54 and 55, or the like, occur as shown in FIG. 17, so that the yield of the chips is again lowered. In the following, the function that shows the relationship between the etching time and the yield, as shown in FIG. 18, is referred to as yield-etching time function σ (t).

Here, conventionally, the etching rate disperses in the respective chips formed on wafers. In addition, even in the inside of the same chip there are some cases wherein the etching rate shows locally different values due to a variety of factors such as the concentration of the pattern formed through etching, dimensions (diameters) in the hole pattern, or the like, formed through etching or the thickness of the layer removed through etching. Therefore, the period of time for carrying out the actual etching process is set to be slightly longer than the expected period of time needed for etching termination.

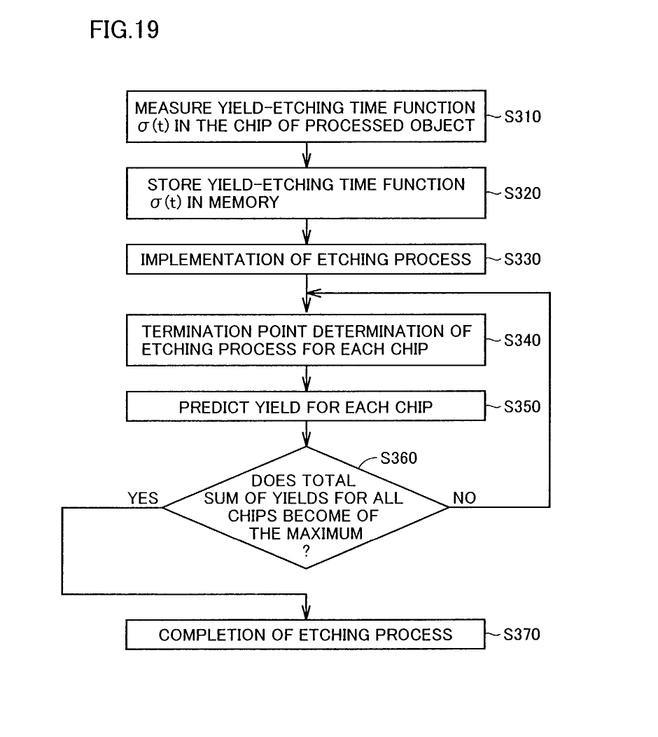

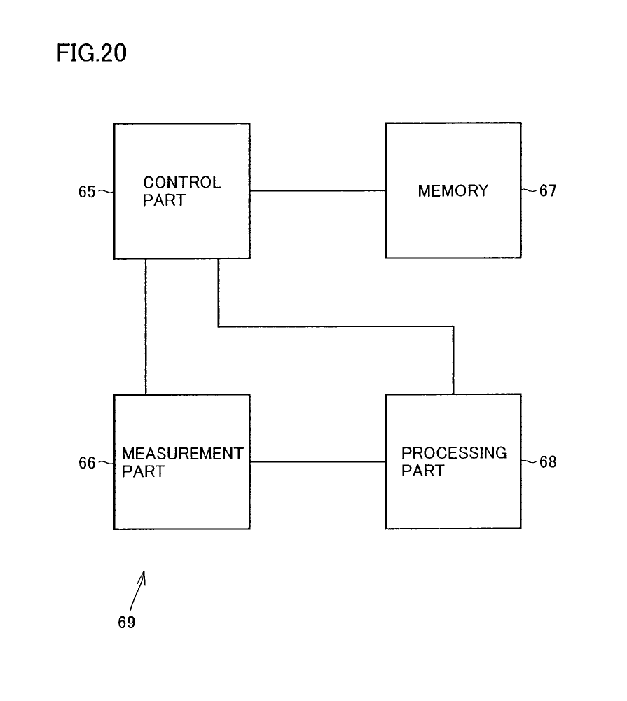

An etching process termination point determining method according to the present invention utilizing the above described yield-etching time function σ (t) is described in the following referring to FIGS. 19 and 20. Here, the case wherein an aluminum alloy film formed on the surface of a wafer is etched in an etching apparatus is described in the following.

Referring to FIGS. 19 and 20, an etching apparatus 69 is provided with a processing part 68 for carrying out an etching process, a measurement part 66 for carrying out a termination point determination, a control part 65 for controlling measurement part 66 as well as processing part 68, and a memory 67 that is a memory unit for storing data used in this control part 65. The step of termination point determination as shown in FIG. 19 is implemented in control part 65, which corresponds to a unit for introducing a period of time of excessive processing and to the determination unit. In addition, as for the concrete apparatus configuration of the etching apparatus, the configuration of the etching apparatus shown in the first embodiment of the present invention can be used.

In the etching apparatus as shown in FIG. 20, the termination point determining method shown in FIG. 19 is carried out. Concretely, referring to FIG. 19, the step (S310) of measuring the yield-etching time function σ (t) in the chip region of the processed object as the correlation is implemented first in etching apparatus 69. Concretely, a plurality of etching processes are carried out by changing the period of time of etching in a variety of ways in this etching apparatus 69 so as to find the value of the probability of gaining a good product in the chip region for every period of time of etching.

Next, the step (S320) of storing the yield-etching time function σ (t) measured in the above described step (S310) in memory 67 is implemented.

Next, the step (S330) of carrying out the etching process for etching an aluminum alloy film formed on a wafer is actually implemented. In this etching process, as described in the first embodiment, or the like, of the etching apparatus according to the present invention, the irradiation step of irradiating the surface of the wafer with monochromatic light by using light projection part 7 included in measurement part 66 is implemented. As for light projection part 7, it is preferable to include a unit for changing the wavelength of the irradiated light. Then, the reflected light detection step wherein the reflected light that has resulted from reflection of the above light from the wafer surface is detected in light reception part 9, which is included in measurement part 66, is implemented.

At this time, as has already been described, since reflected light from respective chip regions on the surface of the wafer is distinguished in light reception part 9, it can be easily determined whether or not the aluminum alloy film, which is the etched object in this chip, has been completely removed through etching (whether or not the etching is completed) based on the data of the reflected light (change in intensity of the reflected light) from the respective chip regions. Concretely, the intensity of the reflected light from these chip regions is approximately a constant while the aluminum alloy film is being removed through etching.

However, portions wherein the etching of the aluminum alloy film is completed in a chip (portions wherein the aluminum alloy film is almost completely removed through etching so that the surface of the base film located beneath the aluminum alloy film has become exposed) are gradually generated. The intensity of light that has reflected from the surface of the aluminum alloy film and the intensity of the reflected light from the surface of the base film differ from each other (intensity of light reflected from the surface of the base film is lower than the intensity of the reflected light from the surface of the aluminum alloy film). Accordingly, after the portions wherein such etching is completed have been generated, the intensity of the reflected light from that chip region is gradually lowered. Then, when the etching of the aluminum alloy film has been almost completed on the surface of this chip region, the intensity of the reflected light from this chip region is suddenly lowered and has an approximately constant value.

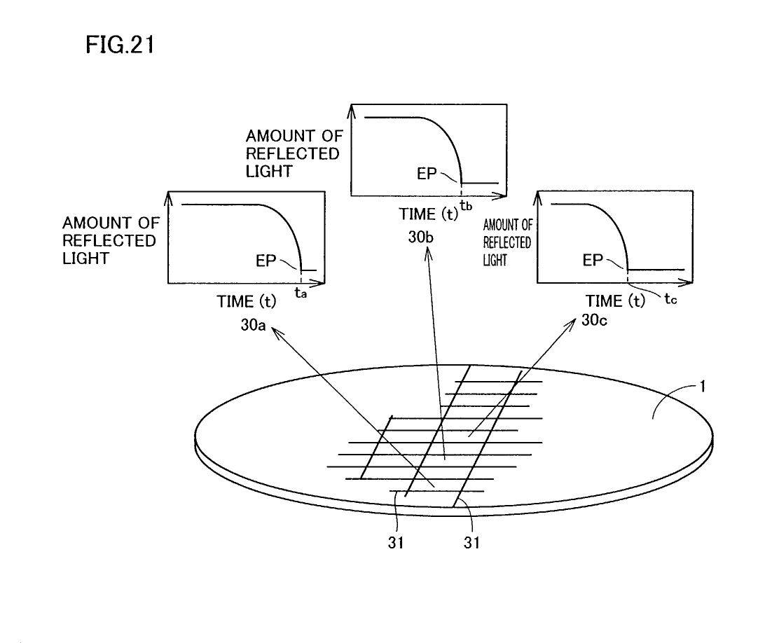

By measuring a change in the intensity of such reflected light in the light reception part, the step (S340) of determining the termination point of the etching process is implemented for each chip region (also referred to as chip). The step (S340) of determining the termination point of the etching process (point in time when the etching process is completed) for each chip region, which is the above described determination step, is described in detail referring to FIG. 21. In FIG. 21 a graph is represented showing the relationship between the reflected light amount, which is intensity information of the reflected light, and the etching time for each of chip regions 30a to 30c. In each of the graphs the longitudinal axis shows the reflected light amount and the lateral axis shows the etching time, respectively.

Referring to FIG. 21, a plurality of chip regions, which are surrounded by dicing lines 31 and which are arranged in a matrix, are formed on the surface of wafer 1. Attention is particularly directed to chip regions 30a to 30c from among the plurality of chip regions, which are described in the following. In chip region 30a that is located in the peripheral portion of wafer 1, the etching rate of the portion wherein this chip region 30a is located is comparatively lower than that in the other regions. Therefore, as shown in FIG. 21, the period of time from the start of etching to the completion of etching becomes long in chip region 30a. That is to say, the period of time from the point in time when the etching process is started to the point in time tₐ when the end point (EP) is detected becomes long for chip region 30a.

In addition, in chip region 30b, which is located to the inside of chip region 30a, the etching rate is slightly higher than in chip region 30a. Therefore, the period of time from the point in time when the etching process is started to the point in time t_{b} when the end point is detected becomes shorter than that of chip region 30a.

In addition, with respect to chip region 30c located in approximately the center portion of wafer 1, the etching rate comparatively higher than that in chip regions 30a and 30b. Therefore, the period of time from the point in time when the etching process is started to point in time t_{c} when the end point is detected becomes shorter than the corresponding period of time in chip region 30a or 30b.

Here, a change in the reflected light as described above occurs in the same manner as for the reflected light from the entirety of wafer 1. The areas of chip regions 30a to 30c, however, are significantly smaller than the area of the upper surface of wafer 1. Accordingly, factors that influence the etching such as plasma concentration, radical concentration, the flow of the reactive gases, and the like, with respect to each of chip regions 30a to 30c can be regarded as being approximately a constant for each of chip regions 30a to 30c. That is to say, with respect to each of chip regions 30a to 30c, the uniformity of the etching within the chip region is significantly higher than the uniformity of the etching throughout the entirety of wafer 1. Accordingly, as shown in FIG. 21, the change in the reflected light amount is precipitously dramatic so that the end point (termination point of etching) for each chip region can be found with a high precision (the point of change wherein the reflected light amount shows a constant value after being sharply lowered is considered to be the end point (termination point of etching), as shown in FIG. 21).

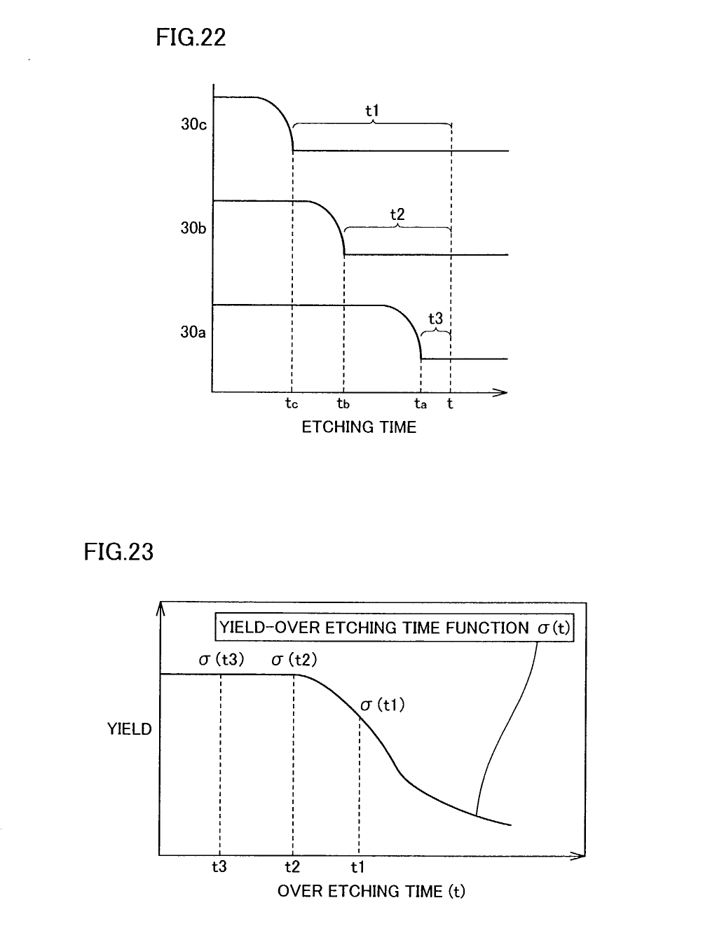

Here, after the point in time when the end point is detected, the respective chip regions are considered to have undergone over etching. That is to say, with respect to each of chip regions 30a to 30c, the amount of time of undergoing etching after the point in time tₐ to t_{c} is the over etching time, which is the excessive processing time. In the following, a description is given referring to FIG. 22.

Referring to FIG. 22, attention is directed to a certain point in time t after the end point during the period of time when etching is being carried out. Then, with respect to chip region 30a, period of time t3 from point in time tₐ to point in time t is the period of time of over etching. In the same manner, with respect to chip region 30b, period of time t2 from point in time t_{b} to point in time t is the period of time of over etching. In addition, with respect to chip region 30c, period of time t1 from the point in time t_{c} to the point in time t is the period of time of over etching.

Next, as shown in FIG. 19, the step (S350) of predicting the yield for each of the chip regions (probability of gaining a good product) is implemented. Concretely, the step of introducing the above described period of time of over etching tx is implemented for each of the chip regions. Then, the yield-etching time function (correlation) showing the relationship between this period of time of over etching tx and the yield (probability of gaining a good product) is found from the yield-etching time function σ (t) shown in FIG. 18. Concretely, the point in time when the etching is completed is assumed to be 0 and a point in time after the point in time when the etching is completed is assumed to be over etching time tx along the lateral axis represented by the period of time of etching (t). Then, by using this yield-etching time function, the yield σ (tx) that corresponds to the over etching time tx for each of the chip regions at a certain point in time is predicted. Here, x is an integer from 1 to n and n is the total number of chip regions formed on wafer 1. Such step of finding the yield for each chip region is described by using chip regions 30a to 30c.

As shown in FIG. 22, the respective over etching time of chip regions 30a to 30c are t3 to t1 . Then, by applying such data of the over etching time t1 to t3 at a certain point in time t to the above described yield-etching time function Γ (t) (also referred to as correlation function), the yields σ (t3) to σ (t1) (probabilities of gaining good products) in the respective chip regions 30a to 30c can be gained as shown in FIG. 23. The values σ (t3) to σ (t1) of the predicted yields with respect to the respective chip regions 30a to 30c found in such a manner show the predicted values of the yields of the chip regions 30a to 30c at the point in time t.

Next, in the step (S350) the evaluation value Σσ (tx) (here x=1 to 3), which is the total sum of the values of the above predicted yields, is found. As a result of this, the evaluation value of the entirety of the yields of chip regions 30a to 30c at point in time t can be gained. Here, the above described method can be applied in the same manner to the case wherein the number of chip regions is greater than three. That is to say, the over etching time is found for each of the n chip regions and the value of the predicted yield is found for each of the chip regions from the above over etching time by using the yield-over etching period of time function shown in FIG. 23. Then, the total sum of the values of these predicted yields Σσ (tx) (here x=1 to n) is found.

Here, in the actual etching process, the evaluation value of the yield of the entirety of the chips Σσ (tx) starts increasing from 0 at the point in time when the etching is first completed (when the end point is detected) in the chip region wherein the etching rate is comparatively fast. Then, the above described evaluation value shows the maximum value at a stage when a certain period of time has passes and starts to fall when additional time has passed.

Then, after finding the total sum value (evaluation value) of the yields with respect to the entirety of the chips as described above, the step (S360) of verifying whether or not the total sum value of the yields has become of the maximum is implemented as the determination step. In such a manner, point in time t, when the total sum value of the yields with respect to the entirety of the chips becomes of the maximum, is the point in time of the completion of etching, when the maximum yield can be gained in the wafer under those process conditions. Accordingly, by completing the etching process at this point in time, it becomes possible to realize the maximum yield under these process conditions. That is to say, in the case that the total sum of the yields with respect to the entirety of the chips becomes of the maximum, the step (S370) of completing the etching process is implemented. On the other hand, in the case that the above described total sum of the yields with respect to the entirety of chips has not become of the maximum, the steps after step (S340) are again repeated.

Thus, in the case that the uniformity of the etching or the period of time of etching have changed together with the change of the variety of plasma characteristics due to the alteration, for example, of the process conditions such as etching, it becomes possible to complete the etching process according to the timing when the maximum yield can be gained under the conditions after that change by using the termination point detection method shown in FIG. 19. As a result of this, the number of chips that can be gained as good products from the same wafer can be increased. Accordingly, the productivity of the chip can be increased.

Here, with respect to a wafer for manufacturing chips of types different from the above described chips, a correlation function that has measured the relationship between the yield and the etching time (over etching time) is prepared in advance as shown in FIG. 18 or FIG. 23 so as to be stored in memory 67 of etching apparatus 69 and, thereby, the yield in the etching process for the above described wafer for manufacturing different types of chips can also be maximized in the same manner as in the above. As a result of this, the productivity of the chip can be increased in the same manner.

In addition, though in the above described example the over etching time tx is used at the time of the prediction of the yield for each of the chip regions, the yield of each of the chips may be found by using the etching time in a chip region instead of the above over etching time tx. In this case, the same effects can also be gained.

(Sixth Embodiment)

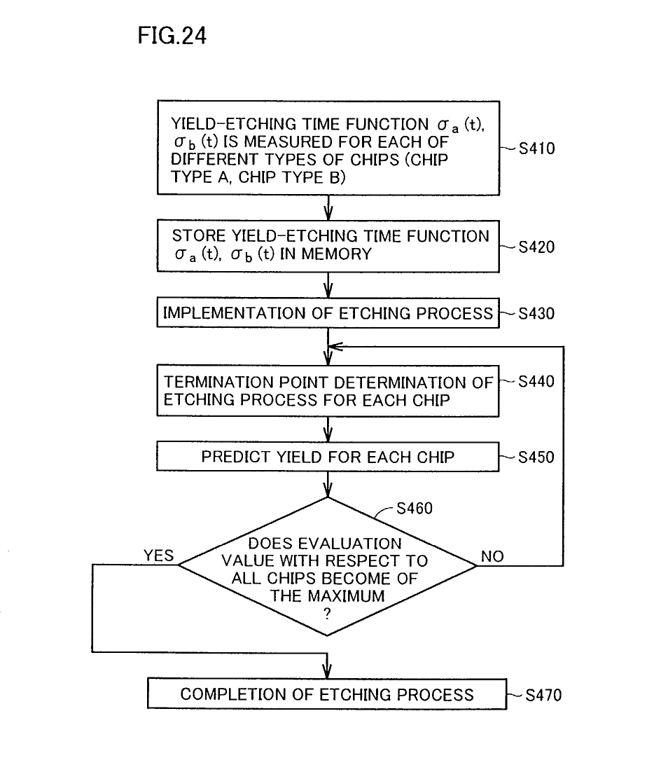

Referring to FIG. 24, a sixth embodiment of a termination point determining method in an etching apparatus according to the present invention. Here, the termination point determining method shown in FIG. 24 can be carried out in an etching apparatus 69 shown in FIG. 20 in the same manner has the termination point determining method shown in the fifth embodiment of the present invention. The termination point determining method shown in FIG. 24 is carried out in control part 65 that corresponds to a unit for deriving the plurality of excessive processing periods of time shown in FIG. 20, a unit for finding the value of the probability of gaining a good product with respect to the plurality of semiconductor chips and a decision unit. In addition, as for the concrete apparatus configuration of the etching apparatus, the configuration of the etching apparatus shown in the first embodiment of the present invention can be used.

The termination point determining method shown in FIG. 24 is applied to the case wherein different types of chips are formed within one wafer, unlike in the case wherein one type of chips are formed on one wafer as shown in the fifth embodiment of the present invention. In the case that different types of chips (plurality of types of semiconductor chips) are formed within one wafer in the above manner, the etching rate or the correlation curve between the yield and the over etching period of time differ for each type in the chip region. In addition, there is a case wherein the priorities differ among different types according to the difference in profit ratios or in apparatus selling prices. An example wherein two types of chips are mixed within one wafer is described in the following.

Referring to FIG. 24, first, the step (S410) of measuring yield-etching time functions σₐ (t) and σ_{b} (t) as the first and second correlations is carried out for each of the different types of chips (chip type A and chip type B). In the step (S410), that is the step of finding the first and second correlations, the same step as the step (S310) shown in FIG. 19 is carried out for each of the chip types A and B and, thereby, the yield-etching time functions σₐ (t) and σ_{b} (t) are gained.

Next, the step (S420) of storing the yield-etching time functions σₐ (t) and σ_{b} (t) in a memory is implemented. This step corresponds to the step (S320) in FIG. 19.

Next, the step (S430) of carrying out the etching process is implemented in the etching apparatus. This step (S430) corresponds to the step (S330) in FIG. 19. In this etching process, as described in the first embodiment, or the like, of the etching apparatus according to the present invention, the irradiation step of irradiating the surface of the wafer with a monochromatic light by using a light projection part 7, or the like, included in measurement part 66 (see FIG. 20). As for light projection part 7, it is preferable to include a unit for changing the wavelength of the irradiated light. Then, the reflected light detection step is implemented of detecting the reflected light resulting from the reflection of the above light from the wafer surface in a light reception part 9 that is included in measurement part 66.

Next, the step (S440) of carrying out the termination point determination of the etching process for each chip is implemented. In this step (S440) the same process as in the step (S340) in FIG. 19 is carried out. Here, the over etching period of time is found as the first excessive processing period of time with respect to the chip region of the chip type A and, at the same time, the over etching time is found as the second excessive processing period of time with respect to the chip region of the chip type B.

Next, the step (S450) of predicting the yield for each chip is implemented as the step of finding the value of the probability of gaining a good product with respect to the plurality of semiconductor chips. This step corresponds to the step (S350) in FIG. 19. Here, in the termination point detection method shown in FIG. 24, two types of chips, chip type A and chip type B, are formed on the wafer. Therefore, the yield is predicted for each chip region based on the over etching period of time and the yield-over etching period of time function (correlation curve) for each chip region according to the type of each chip. Here, the yield-over etching period of time function can be found from the above described yield-etching time functions σₐ (t) and σ_{b} (t) in the same manner as in the case of the step shown in FIG. 19.

Here, in addition to the assumption that the priority of the chip type A is k times as large as the chip type B, the evaluation value with respect to the entirety of the chip regions is derived by taking this priority into consideration. That is to say, when the first coefficient with respect to the chip type A is k and the second coefficient with respect to the chip type B is set at one, the evaluation value represented as the evaluation value=Σkσₐ (tx1)+Σσ_{b} (tx2) is used. Here, x1=1 to nₐ, x2=1 to n_{b}, where nₐ and n_{b} respectively show the numbers of chip regions that correspond to each of the chip type A and chip type B in the wafer. Here, when the second coefficient with respect to the chip type B is m, the evaluation value shown as evaluation value=Σkσₐ (tx1)+Σmσ_{b} (tx2) may be used.

After calculating such an evaluation value, the step (S460) of verifying whether or not the evaluation value has become of the maximum as the decision step. Then, in the case that this evaluation value has become of the maximum, the step (S470) of completing the etching process is carried out. In addition, in the case that the evaluation value has not become of the maximum, the steps after the step (S440) are again repeated.

Thus the completion point in time of etching by using the evaluation value that has the priority (coefficient k) taken into consideration is determined and, thereby, the yield can be maximized by taking the priorities of the different chip types A and B into consideration.

Here, in the case that the difference between the priorities of the chip types A and B is not particularly set, k=1 is set in the above described equation for calculating the evaluation value. In addition, in the case that there are more than two types of chip types, the termination point of etching process can be determined in the case that the evaluation value is calculated in the same method. That is to say, in the case that there are three types, or more, of chips, the yield-over etching period of time function is found in advance for each type and the yield (probability of gaining a good product) is calculated in accordance with the type of chip region. Then, the evaluation value can be derived by summing up the values gained by multiplying the yields of the respective chip regions by the coefficients showing the priorities. Then, when the etching process is completed according to the timing wherein the evaluation value becomes of the maximum, the yield of each of the chips gained from the wafer can be maximized by taking the priority for the chip type into consideration.

Here, in the termination point determining method shown in FIG. 24, it is necessary to recognize in advance which chip regions correspond to which types with respect to the chip regions on the wafer 3. As for the method for allowing the control part of the etching apparatus to recognize such types and positions in the chip region on the wafer, the following method can, for example, be used.

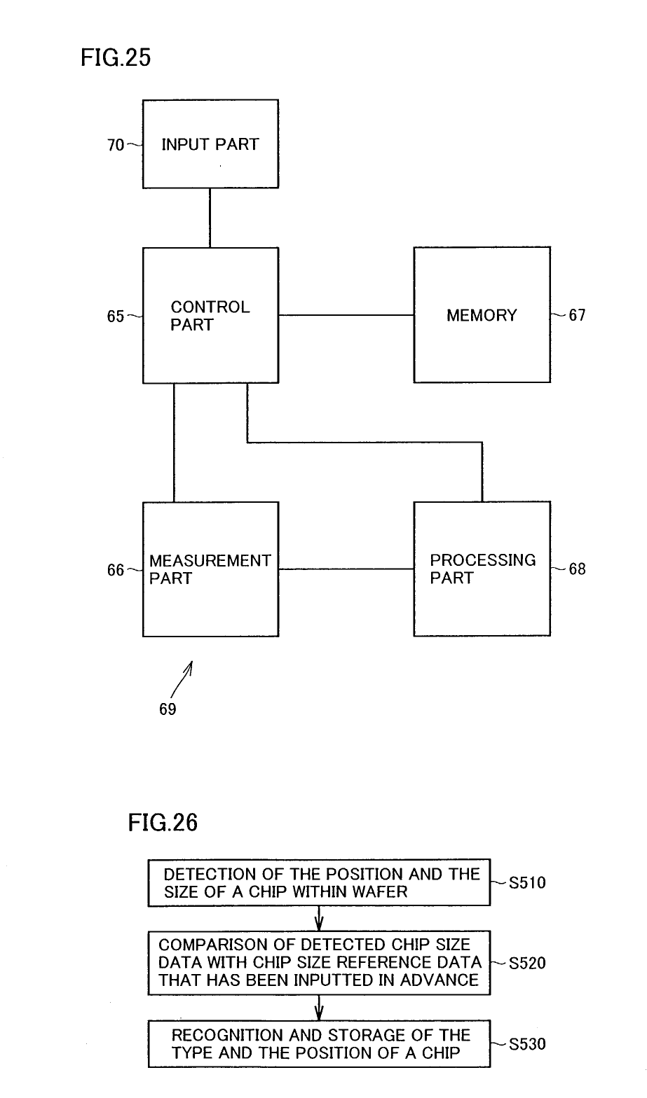

Referring to FIG. 25, an etching apparatus has the similar configuration to the etching apparatus in the fifth embodiment according to the present invention shown in FIG. 20 while an input part 70 connected to the control part 65 is provided. Then, the position of the chip region within the wafer, which is recognized by using the method shown in the third embodiment of the present invention, is displayed on a CRT, or the like, that is provided to this input part 70. In addition to that, the arrangement of the chip regions within the wafer that is known in advance and the arrangement of the chip regions within the wafer displayed on the CRT, or the like, are compared by the operator. Then, by using an input apparatus included in this input part 70 such as, for example, a keyboard or a touch panel provided on the display part, a technique can be used wherein the operator inputs information that specifies the types and positions of the respective chips.

In addition, as for the method of specifying the chip types that respectively correspond to the chip regions to which different chip types formed on the wafer correspond in the etching apparatus, an automatic recognition may be carried out based on the position information and the size information of the chip regions as described below.

Referring to FIG. 26, first, the step (S510) of detecting the position and the size of the chip region within the wafer is implemented. In this step (S510), the same technique as of the determination method of the chip region described in the third embodiment of the present invention can be used. That is to say, dicing lines formed within the wafer are detected based on the difference in the reflectance of light between that from the chip regions and that from the dicing lines and, thereby, the region surrounded by the dicing lines is recognized as a chip region. Then, by detecting the comparative position, the form of the outer periphery and the size of this chip region are detected within the wafer and, thereby, the step (S510) that is the step of distinguishing each form of the outer periphery of the region in which a semiconductor chip is to be formed can be implemented. Here, first, the positions of the respective chip regions are specified.

Next, the step (S520) of comparing the chip size reference data that is outer periphery form reference data including reference data concerning the size and the form of the outer periphery of a semiconductor chip region, which is inputted in the apparatus in advance and which is stored in a memory, or the like, with the size and form data (chip size data) of the detected chip region is implemented. Here, in the case that the chip size and the form of the outer periphery differ for each chip type, the type of this chip region can be specified from the size or the form of the outer periphery.

After this, the step (S530) of recognizing the type and the position of the chip region, which are stored in a memory, or the like, is implemented.

Here, as for the method of detecting the size of the chip region, a technique of calculating the size of the detected chip region from the corresponding relation between the diameter of the measured wafer and the number of the CCD cells in the light reception part can be used.

The automatic recognition described above may be performed in control part 65 (see FIG. 25). The control part 65 corresponds to a unit for distinguishing the positions and the respective forms of the outer peripheries of the regions of the semiconductor substrate in which a plurality of semiconductor chips are to be formed and a unit for specifying the type of a plurality of semiconductor chips by comparing the respective forms of the outer peripheries of the regions.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor processing apparatus for carrying out a process on a semiconductor substrate on which a plurality of semiconductor chips are to be formed, comprising:
an irradiation unit for irradiating a surface of said semiconductor substrate on which said plurality of semiconductor chips are to be formed with light at the time when the process is carried out on said semiconductor substrate;
a reflected light detection unit for detecting a plurality of reflected light beams, from among the light with which the surface of said semiconductor substrate is irradiated, that are respectively reflected from regions in which said plurality of semiconductor chips are to be formed; and
a determination unit for detecting a plurality of termination points that are points in time when said process is completed concerning respective processes carried out on the regions in which said plurality of semiconductor chips are to be formed based on information gained by detecting said plurality of reflected light beams.

2. The semiconductor processing apparatus according to claim 1, wherein said information is intensity information of said plurality of reflected light beams.

3. The semiconductor processing apparatus according to claim 1, comprising:
a memory unit for storing a correlation between the probability of gaining a good product with respect to a specific semiconductor chip formed on said semiconductor substrate and the excessive processing period of time during which said process is continued after said termination point to be continued the region on which said semiconductor chip is to be formed;
a unit for introducing a plurality of excessive processing periods in time in the case that the process is continued from said plurality of termination points to a point in time after said plurality of termination points in the plurality of regions in which said plurality of semiconductor chips are to be formed; and
a decision unit for deciding the point in time when an evaluation value decided based on said plurality of excessive processing period of time and said correlation stored in said memory unit becomes of the maximum to be used as the completion point in time of said process.

4. The semiconductor processing apparatus according to claim 3, wherein said evaluation value is a value gained by summing up the probabilities of gaining good products for the plurality of semiconductor chips that are found from said plurality of excessive processing periods of time and from said correlations in said decision step.

5. The semiconductor processing apparatus according to claim 1,
wherein said plurality of semiconductor chips include a plurality types of semiconductor chips,
wherein said determination unit performs detection of a plurality of termination points that are the points in time when said process is completed for respective processes carried out on the plurality of regions in which said plurality of types of semiconductor chips are to be formed, and
wherein said apparatus comprises:
a memory unit for storing a correlation between the probability of gaining a good product of a corresponding type of semiconductor chip for each type of semiconductor chips formed on said semiconductor substrate and the excessive processing period of time during which said process is continued after the point in time when said process is completed on the region in which said corresponding type of semiconductor chip is to be formed;
a unit for introducing the excessive processing period of time in the corresponding region in the case that the process is continued to be carried out from said termination point to a point in time after the termination point in the corresponding region for each of the plurality of regions in which said plurality of types of semiconductor chips are to be formed;
a unit for finding a value of the probability of gaining a good product of a semiconductor chip formed in the corresponding region based on said excessive processing period of time in the corresponding region and on said correlation found for each type of semiconductor chips formed in the corresponding region with respect to each of the plurality of regions in which said plurality of types of semiconductor chips are to be formed; and
a decision unit of deciding the point in time when the total sum of said values of the probabilities of gaining good products of said plurality of types of semiconductor chips becomes of the maximum as the completion point in time of said process.

6. The semiconductor processing apparatus according to claim 1,
wherein said plurality of semiconductor chips include a plurality of types of semiconductor chips,
wherein said determination unit performs detection of a plurality of termination points that are points in time when said process is completed for respective processes carried out on the plurality of regions in which said plurality of types of semiconductor chips are to be formed, and
wherein said apparatus comprises:
a memory unit for storing a plurality of coefficients indicating the respective priorities set for each of the types of said semiconductor chips formed on said semiconductor substrate, a correlation, found for each of the types of said semiconductor chips formed on said semiconductor substrate, between the probability of gaining a good product of a semiconductor chip of the corresponding type and the excessive processing period of time during which said process is continued after the point in time when said process is completed to be carried out on the region in which said corresponding type of semiconductor chips are to be formed;
a unit for introducing the excessive processing period of time in the corresponding region in the case that the process is continued to be carried out on the corresponding region from said termination point to a point in time after said termination point for each of the plurality of regions in which said plurality of types of semiconductor chips are to be formed;
a unit for finding the value of the probability of gaining a good product of a semiconductor chip formed in the corresponding region based on said excessive processing period of time in the corresponding region and said correlation found for each of the types of the semiconductor chips formed in the corresponding region concerning the plurality of regions in which said plurality of types of semiconductor chips are to be formed; and
a decision unit for deciding the point in time when the priority evaluation value derived based on the value of the probability of gaining a good product with respect to said plurality of types of semiconductor chips and on a coefficient set for each of the types of said semiconductor chips becomes of the maximum as the completion point in time of said process.

7. The semiconductor processing apparatus according to claim 6, wherein said priority evaluation value is gained by summing up the values gained by multiplying the values of said probabilities of gaining good products for said plurality of types of semiconductor chips by said coefficient set for each type of corresponding semiconductor chip with respect to said plurality of types of semiconductor chips.

8. The semiconductor processing apparatus according to claim 1, comprising a unit for distinguishing the positions of the regions of said semiconductor substrate in which said plurality of semiconductor chips are to be formed based on the difference in the reflectance of light between the regions wherein said plurality of the semiconductor chips are to be formed and the regions other than the regions wherein said plurality of the semiconductor chips are to be formed on the surface of said semiconductor substrate.

9. The semiconductor processing apparatus according to claim 1, comprising: a unit for distinguishing the respective forms of the outer peripheries of the regions of said semiconductor substrate in which said plurality of semiconductor chips are to be formed based on the difference in the reflectance of light between the regions wherein said plurality of the semiconductor chips are to be formed and the regions other than the regions wherein said plurality of the semiconductor chips are to be formed on the surface of said semiconductor substrate; and
a unit for specifying the type of said plurality of semiconductor chips by comparing the respective forms of the outer peripheries of regions in which said plurality of semiconductor chips are to be formed with the outer periphery formation reference data according to the type of semiconductor chips.

10. The semiconductor processing apparatus according to claim 1, wherein a light projection member for irradiating said surface of said semiconductor substrate with light with respect to said irradiation unit includes a unit for changing the wavelength of said light.

11. The semiconductor processing apparatus according to claim 10,
wherein said light projection member includes a light source for radiating light of a plurality of wavelengths, and
wherein said unit for changing the wavelength of light includes a filter member that allows light of an arbitrary wavelength to pass through from among light radiated from said light source.

12. The semiconductor processing apparatus according to claim 1, wherein said process is a process using a plasma.

13. The semiconductor processing apparatus according to claim 12, wherein the wavelength of light with which said semiconductor substrate is irradiated differs from the wavelength of the light component in the light emission from said plasma having a comparatively great emission intensity.

14. The semiconductor processing apparatus according to claim 1, wherein said irradiation unit irradiates said surface of said semiconductor substrate with a monochromatic light.

15. A manufacturing method for a semiconductor device using a semiconductor processing apparatus according to claim 1.
